(19) United States
(12) Patent Application Publication
(10) Pub. No.: US 2010/0122795 A1
(43) Pub. Date: May 20, 2010

(54) HEAT DISSIPATION DEVICE

(75) Inventors: Wu Li, Shenzhen City (CN); Yi-Qiang Wu, Shenzhen City (CN); Chun-Chi Chen, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: Fu Zhun Precision Industry (Shen Zhen) Co., Ltd., Shenzhen City (CN); Foxconn Technology Co., Ltd., Tu-Cheng (TW)

(21) Appl. No.: 12/346,884

(22) Filed: Dec. 31, 2008

(30) Foreign Application Priority Data
Nov. 14, 2008 (CN) 200810305563.6

(51) Int. Cl. F28F 7/00; F28D 15/00; H05K 7/20

(52) U.S. Cl. 165/80.2; 165/104.21; 165/185; 361/709

(57) ABSTRACT

A heat dissipation device includes a heat sink, a plurality of heat pipes extending in the heat sink, a heat-conducting plate attached to the heat pipes, and a mounting member located between the heat sink and the heat-conducting plate and firmly securing the heat pipes to the heat-conducting plate. The mounting member includes a mounting base and a mounting board mounting on the mounting base. The heat pipes extending through the mounting base are received in the heat-conducting plate. The mounting board spanning the mounting base and the heat pipes press the heat pipes towards the heat-conducting plate via fasteners extending through the mounting base and screwing in the mounting board, whereby the heat pipes have an intimate contact with the heat-conducting plate.

### BACKGROUND OF THE INVENTION

1. Field of the Invention

The disclosure relates generally to heat dissipation devices and, more particularly, to a heat dissipation device having heat pipes and a mounting member for mounting the heat pipes on a bottom of the heat dissipation device.

2. Description of Related Art

Computer electronic components, such as central processing units (CPUs), generate great amounts of heat during normal operation. If the heat is not properly dissipated, it can deteriorate an operational stability of the electronic components and damage associated electronic devices. Thus, the heat must be removed quickly to ensure normal operation of these electronic components. A heat dissipation device is often attached to a surface of a CPU to remove heat therefrom.

A typical heat dissipation device attached to a CPU includes a base, a plurality of fins arranged on the base, and a plurality of heat pipes extending in the base and the fins. A plurality of grooves is defined in the base, and a plurality of holes is defined in the fins. Each heat pipe has a bent configuration and includes an evaporating section received in a corresponding groove of the base and a condensing section extending from the evaporating section. The condensing section is inserted into a corresponding hole of the fins. However, the heat pipes are often directly secured in the grooves of the base by soldering or adhering, and results in a poor stability between the heat pipes and the base, particularly when the number of the heat pipes increases. Additionally, when the base of the heat dissipation device has a small contacting surface with the heat pipes and a large space between the base and the fins is required, the heat pipes directly attached to the base can not satisfy the demand, whereby a mounting member for reliably and securely mounting the heat pipes on the base is needed.

What is needed, therefore, is a heat dissipation device with an enhanced mounting member.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an exploded, isometric view of a heat dissipation device in accordance with an embodiment of the present disclosure.

FIG. 2 is an inverted view of the heat dissipation device in FIG. 1.

FIG. 3 is a partially assembled view of the heat dissipation device in FIG. 1.

FIG. 4 is an assembled view of FIG. 1.

### DETAILED DESCRIPTION OF THE EMBODIMENTS

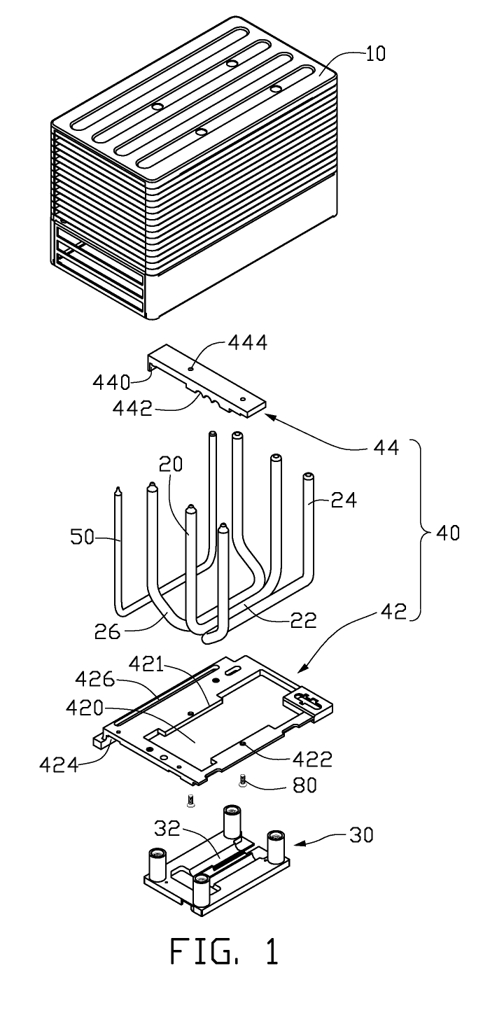

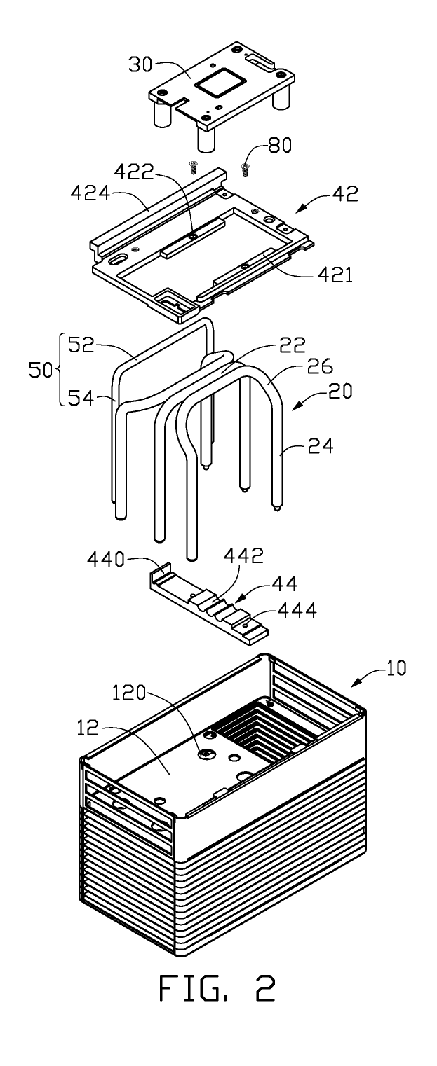

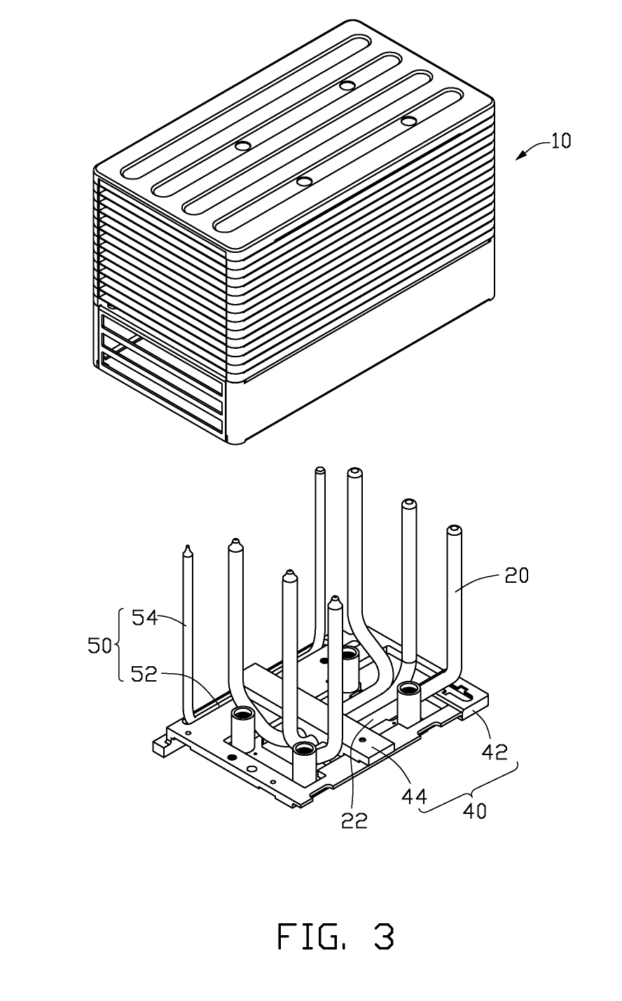

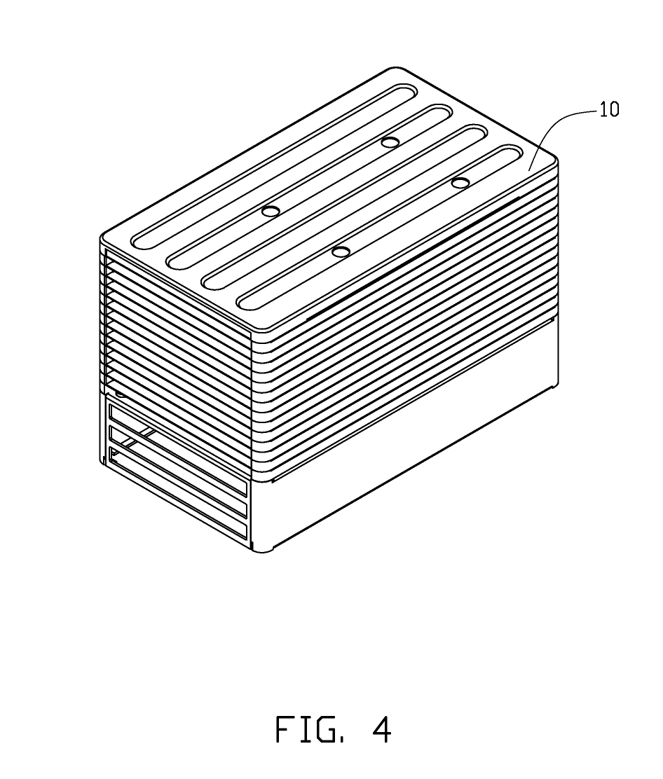

Referring to FIGS. 1-4, a heat dissipation device in accordance with one embodiment of the present invention comprises a heat sink 10, a plurality of heat pipes 20, 50 thermally extending in the heat sink 10, a heat-conducting plate 30 attached to the heat pipes 20 and a mounting member 40 located between the heat sink 10 and the heat-conducting plate 30 for mounting the heat pipes 20 on the heat-conducting plate 30. The heat-conducting plate 30 is adapted for removing heat from a first heat-generating electronic component (not shown) attached to a bottom surface of the heat-conducting plate 30.

The heat sink 10 comprises a plurality of fins 12 substantially parallel to and stacked with each other. Each fin 12 may be formed from a metal sheet with high heat conductivity, such as an aluminum or a copper sheet. Each fin 12 defines a plurality of through holes 120 therein, for extension of the heat pipes 20.

The plurality of heat pipes 20, 50 comprises three first heat pipes 20 and a second heat pipe 50 spaced from the first heat pipes 20. Each first heat pipe 20 comprises an evaporating section 22, a condensing section 24, and a curving section 26 connecting the evaporating section 22 and the condensing section 24. The evaporating sections 22 are parallel and juxtaposed with each other. The condensing sections 24 are substantially perpendicular to the evaporating sections 22 and extend into the through holes 120 of the heat sink 10. The curving sections 26 of the two outermost first heat pipes 20 extend away from the middle one of the first heat pipes 20. The second heat pipe 50 comprises a heat-absorbing portion 52 and a pair of heat-dissipating portions 54 extending substantially perpendicularly from opposite ends of the heat-absorbing portion 52. The heat-absorbing portion 52 is substantially parallel to the evaporating sections 22 of the first heat pipes 20 and the heat-dissipating portions 54 are substantially parallel to the condensing sections 24 of the first heat pipe 20. The heat-dissipating portions 54 extend into the heat sink 10.

The heat-conducting plate 30 may have a rectangular shape and may be made of copper or copper alloy. The heat-conducting plate 30 defines three receiving slots 32 in a top surface, for receiving the evaporating sections 22 of the first heat pipes 20. The three receiving slots 32 are located in a middle portion of the top surface of the heat-conducting plate 30 and substantially parallel to each other. A bottom surface of the heat-conducting plate 30 is attached to the first heat-generating electronic component.

The mounting member 40 comprises a mounting base 42 and a mounting board 44 engaging with the mounting base 42 to fix the first heat pipes 20 to the heat-conducting plate 30. The mounting base 42 may be rectangular and has an area larger than an area of the heat-conducting plate 30 so as to cover the heat-conducting plate 30. An opening 420, corresponding to the receiving slots 32 of the heat-conducting plate 30, is defined in a center portion of the mounting base 42. A pair of strips 421 is formed at opposite inner lateral sides of the opening 420, for pressing the heat-conducting plate 30 towards the first heat-generating electronic component. Each strip 421 defines a mounting hole 422 in a center portion, for extension of a screw 80. The mounting base 42 further comprises a fixing flange 424 extending substantially perpendicularly from a long lateral side thereof, for facilitating to engage with the mounting board 44. An elongated slot 426 is defined in a top surface of the mounting base 42, adjacent to the fixing flange 424, for receiving the heat-absorbing portion 52 of the second heat pipe 50 therein.

The mounting board 44 may be strip-shaped and engages with the mounting base 42 to fix the first heat pipes 20 on the heat-conducting plate 30 and the second heat pipes 50 on the mounting base 42. The mounting board 44 comprises a projecting part 440 extending substantially perpendicularly and downwardly from a short lateral side edge thereof, for clasping the fixing flange 424 of the mounting base 42. Three grooves 442 corresponding to the receiving slots 32 of the heat-conducting plate 30 are defined in a bottom surface of the mounting board 44, for receiving the evaporating sections 22 of the first heat pipes 20. A pair of screw holes 444 in alignment with the mounting holes 422 of the mounting base 42 is defined in the mounting board 44, adjacent to the grooves 442 and, for extension of the screws 80 therethrough to secure the mounting board 44 to the mounting base 42.

In operation, the mounting base 42 is located between the heat pipes 20, 50 and the heat-conducting plate 30, wherein the heat pipes 20, 50 extend into the heat sink 10. The strips 421 of the mounting base 42 are mounted on opposite side edges of the heat-conducting plate 30, for example, by soldering or adhering. The evaporating sections 22 of the first heat pipes 20 extending through the opening 420 of the mounting base 42 are received in the receiving slots 32 of the heat-conducting plate 30, for example, by soldering or adhering. The mounting board 44 spans the evaporating sections 22 of the first heat pipes 20 and the heat-absorbing portion 52 of the second heat pipe 50, with the projecting part 440 abutting against the fixing flange 424 of the mounting base 42. The evaporating sections 22 of the first heat pipes 20 are pressed towards the heat-conducting plate 30 when the mounting board 44 is mounted on the mounting base 42 via the screws 80 extending through the mounting hole 422 and screwed into the screw holes 444. Thus, the evaporating sections 22 of the first heat pipes 20 are kept in intimate contact with the top surface of the heat-conducting plate 30 and absorb heat generated by the first heat-generating electronic component attached to the bottom surface of the heat-conducting plate 30. The heat-absorbing portion 52 of the second heat pipe 50 absorbs heat generated by a second heat-generating electronic component (not shown) attached to a bottom surface of the mounting base 42 adjacent to the fixing flange 424.

Since the mounting member 40 having the mounting base 42 engaging with the mounting board 44 has a compact structure, a space between the heat sink 10 and heat-conducting plate 30 is larger, when the mounting member 40 secures the heat pipes to the heat-conducting plate 30. Moreover, because of the mounting member 40, the first heat pipes 20 are mounted on the heat-conducting plate 30, thereby enabling the first heat pipes 20 to have an intimate contact with the heat-conducting plate 30. Due to a provision of the mounting member 40, stability of the first heat pipes 20 on the heat-conducting plate 30 greatly increases. In addition, the stability of the second heat pipe 50 is also increased.

It is believed that the present disclosure and its advantages will be understood from the foregoing description, and it will be apparent that various changes may be made thereto without departing from the spirit and scope of the disclosure or sacrificing all of its material advantages, the examples hereinbefore described merely being preferred or exemplary embodiments.

What is claimed is:

1. A heat dissipation device, comprising:
a heat sink;
a plurality of heat pipes extending in the heat sink;
a heat-conducting plate comprising a first face adapted for contacting with a heat-generating electronic component and a second face opposite to the first face, the second face being attached to the heat pipes; and
a mounting member located between the heat sink and the heat-conducting plate and tightly securing the heat pipes to the second face of the heat-conducting plate, the mounting member comprising a mounting base having a first face attached to the heat-conducting plate and a mounting board mounted on a second face of the mounting base opposite to the first face of the mounting base;
wherein the mounting board spans the mounting base and the heat pipes and engages with the mounting base to press the heat pipes towards the second face of the heat-conducting plate so that the heat pipes have an intimate contact with the second face of the of the heat-conducting plate.

2. The heat dissipation device as claimed in claim 1, wherein the mounting base of the mounting member comprises a pair of strips attached to opposite sides of the heat-conducting plate.

3. The heat dissipation device as claimed in claim 2, wherein the mounting base defines an opening thereof, the strips being located adjacent to the opening and the heat pipes extending through the opening being received in the second face of the heat-conducting plate.

4. The heat dissipation device as claimed in claim 3, wherein the mounting board comprises a projecting part extending from a side edge thereof and fastening one side of the mounting base.

5. The heat dissipation device as claimed in claim 4, wherein the mounting board is mounted on the mounting base via fasteners extending through the mounting base and screwing in the mounting board.

6. The heat dissipation device as claimed in claim 5, wherein the mounting base comprises a fixing flange extending from the one side thereof and abutting against the projecting part of the mounting board.

7. The heat dissipation device as claimed in claim 1 further comprising an additional heat pipe having a heat-absorbing section received in the mounting base and a heat-dissipating section extending into the heat sink.

8. The heat dissipation device as claimed in claim 7, wherein the first face of the mounting base corresponding to the additional heat pipe is adapted for attaching to another heat-generating electronic component.

9. The heat dissipation device as claimed in claim 8, wherein the second face of the heat-conducting plate defines a plurality of receiving slots therein and the heat pipes each comprise an evaporating section received in a corresponding receiving slot.

10. The heat dissipation device as claimed in claim 9, wherein the mounting board defines a plurality of grooves therein corresponding to the receiving slots of the heat-conducting plate, the evaporating sections of the heat pipes extending through passages defined by the grooves and the receiving slots.

11. The heat dissipation device as claimed in claim 10, wherein the second face of the mounting base defines a slot receiving the heat-absorbing section of the additional heat pipe therein.
